(19) United States
(12) Patent Application Publication
(10) Pub. No.: US 2026/0255706 A1
(43) Pub. Date: Aug. 27, 2026

(54) PHOTOELECTRIC CONVERSION APPARATUS AND PHOTOELECTRIC CONVERSION SYSTEM

(71) Applicant: CANON KABUSHIKI KAISHA, Tokyo (JP)

(72) Inventors: DAIKI SHIRAHIGE, Kanagawa (JP); HIROSHI SEKINE, Kanagawa (JP); JUNJI IWATA, Tokyo (JP)

(21) Appl. No.: 19/546,637

(22) Filed: Feb. 23, 2026

(30) Foreign Application Priority Data
Feb. 27, 2025 (JP) 2025-030345

(51) Int. Cl. H10F 39/00

(52) U.S. Cl. CPC H10F 39/8033

(57) ABSTRACT

Photoelectric conversion apparatus includes semiconductor layer having first second surfaces. The semiconductor layer includes first semiconductor region of first conductivity type extending from the first surface toward the second surface, second semiconductor region of the first conductivity type arranged between the first semiconductor region and the second surface to contact the first semiconductor region, third semiconductor region of second conductivity type arranged between the second semiconductor region and the second surface, and fourth semiconductor region of the second conductivity type arranged in contact with the third semiconductor region to surround the second semiconductor region and the third semiconductor region. Width of the second semiconductor region in direction parallel to the first surface is larger than width of the first semiconductor region in the direction, and smaller than width of the third semiconductor region in the direction.

### BACKGROUND

### Field of the Technology

The present disclosure relates to a photoelectric conversion apparatus and a photoelectric conversion system.

### DESCRIPTION OF THE RELATED ART

International Publication No. 2022/158233 describes a pixel applied to a Single Photon Avalanche Diode (SPAD). The pixel includes a p-type semiconductor region, an n-type semiconductor region arranged to extend from the surface of a substrate to the p-type semiconductor region, and a high-concentration n-type semiconductor region surrounded by the n-type semiconductor region. The pixel also includes a hole accumulation region surrounding the p-type semiconductor region and the n-type semiconductor region, and a high-concentration p-type semiconductor region surrounding the n-type semiconductor region. In the arrangement described in International Publication No. 2022/158233, a strong electric field is formed in the vicinity of the surface of the substrate and around the n-type semiconductor region, and a high dark count rate (DCR) can occur.

### SUMMARY

The present disclosure provides a technique advantageous in lowering the DCR.

The present disclosure provides a photoelectric conversion apparatus that includes a semiconductor layer including a first surface and a second surface, wherein the semiconductor layer includes a first semiconductor region of a first conductivity type extending from the first surface toward the second surface, a second semiconductor region of the first conductivity type arranged between the first semiconductor region and the second surface so as to contact the first semiconductor region, a third semiconductor region of a second conductivity type arranged between the second semiconductor region and the second surface, and a fourth semiconductor region of the second conductivity type arranged in contact with the third semiconductor region so as to surround the second semiconductor region and the third semiconductor region, and a width of the second semiconductor region in a direction parallel to the first surface is larger than a width of the first semiconductor region in the direction, and smaller than a width of the third semiconductor region in the direction.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing an example of the arrangement of a photoelectric conversion apparatus according to an embodiment;

FIG. 2 is a view showing an example of the arrangement of the first substrate;

FIG. 3 is a view showing an example of the arrangement of the second substrate;

FIG. 4 is a view showing an example of the arrangement of a photoelectric conversion element and a pixel circuit;

FIGS. 5A to 5C are views for explaining a photon detection operation;

FIG. 6 is a view showing an example of the arrangement of a photoelectric conversion apparatus according to the first embodiment;

FIGS. 7A to 7C are views each showing an example of the arrangement of the photoelectric conversion apparatus according to the first embodiment;

FIG. 8 is a view showing an example of the arrangement of a photoelectric conversion apparatus according to the second embodiment;

FIG. 9 is a view showing an example of the arrangement of a photoelectric conversion apparatus according to the third embodiment;

FIG. 10 is a view showing an example of the arrangement of a photoelectric conversion apparatus according to the fourth embodiment;

FIG. 11 is a view showing the example of the arrangement of the photoelectric conversion apparatus according to the fourth embodiment;

FIG. 12 is a view showing an example of the arrangement of a photoelectric conversion apparatus according to the fifth embodiment;

FIG. 13 is a view showing an example of the arrangement of a photoelectric conversion apparatus according to the sixth embodiment;

FIG. 14 is a view showing an example of the arrangement of a photoelectric conversion apparatus according to the seventh embodiment;

FIGS. 15A to 15C are views each showing an example of the arrangement of the photoelectric conversion apparatus according to the seventh embodiment;

FIG. 16 is a view showing an example of the arrangement of a photoelectric conversion apparatus according to the eighth embodiment;

FIG. 17 is a functional block diagram of a photoelectric conversion system according to the first application example;

FIGS. 18A and 18B are functional block diagrams of a photoelectric conversion system according to the second application example;

FIG. 19 is a functional block diagram of a photoelectric conversion system according to the third application example;

FIG. 20 is a functional block diagram of a photoelectric conversion system according to the fourth application example;

FIGS. 21A and 21B are functional block diagrams of a photoelectric conversion system according to the fifth application example;

FIGS. 22A and 22B are functional block diagrams of a photoelectric conversion system according to the sixth application example; and

FIG. 23 is a functional block diagram of a photoelectric conversion system according to the seventh application example.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In this specification, conductivity types of semiconductor regions different from each other are distinguished as the first conductivity type and the second conductivity type. The first conductivity type is a conductivity type which uses charge with the first polarity as a majority carrier, and the second conductivity type is a conductivity type which uses charge with the second polarity as a majority carrier. In a case where the first polarity is positive, the charge with the first polarity is a hole, the first conductivity type is the p type, the second polarity is negative, the charge with the second polarity is an electron, and the second conductivity type is the n type. To the contrary, in a case where the first polarity is negative, the charge with the first polarity is an electron, the first conductivity type is the n type, the second polarity is positive, the charge with the second polarity is a hole, and the second conductivity type is the p type.

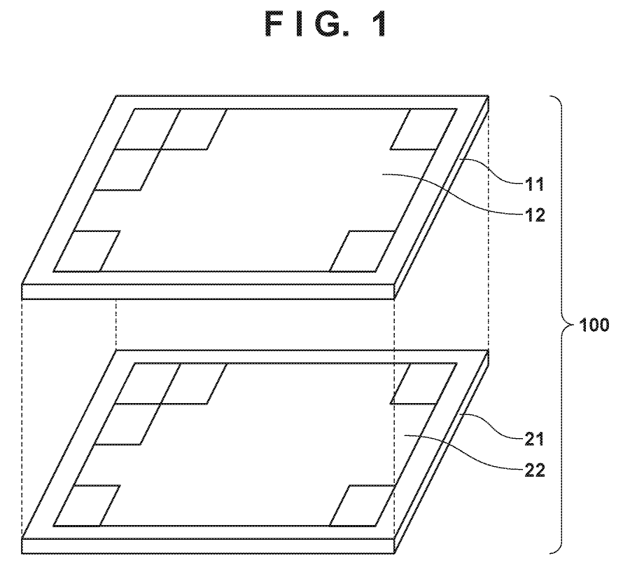

FIG. 1 schematically shows an example of the arrangement of a photoelectric conversion apparatus 100 according to an embodiment of the present disclosure. The photoelectric conversion apparatus 100 can have, for example, a structure in which a first substrate 11 and a second substrate 21 are stacked. The first substrate 11 can include, for example, a photoelectric conversion element array 12 including a plurality of photoelectric conversion elements (avalanche photodiodes or APDs). The second substrate 21 can include a processing circuit 22 that processes signals output from the plurality of photoelectric conversion elements.

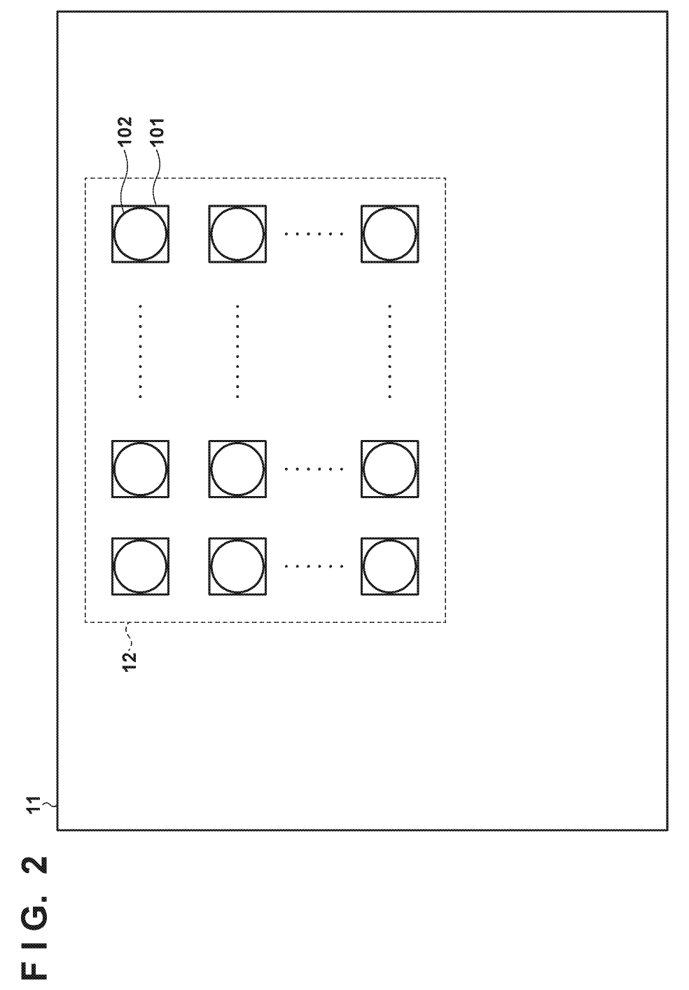

FIG. 2 schematically shows an example of the arrangement of the first substrate 11. The photoelectric conversion element array 12 of the first substrate 11 can include a plurality of photoelectric conversion elements 102 arranged to form a plurality of rows and a plurality of columns. Each photoelectric conversion element 102 constitutes a part of a pixel 101. The photoelectric conversion apparatus 100 will exemplarily be described below as an image capturing apparatus. However, the photoelectric conversion apparatus 100 may be formed as another apparatus. For example, the photoelectric conversion apparatus 100 can be formed as a distance measurement apparatus (for example, a focus detection apparatus or a distance measurement apparatus using TOF (Time Of Flight)) or a photometric apparatus (an apparatus for, for example, measuring an incident light amount) or the like. Note that a plurality of pixels 101 may linearly be arranged. In this case, the photoelectric conversion apparatus 100 can form a line sensor.

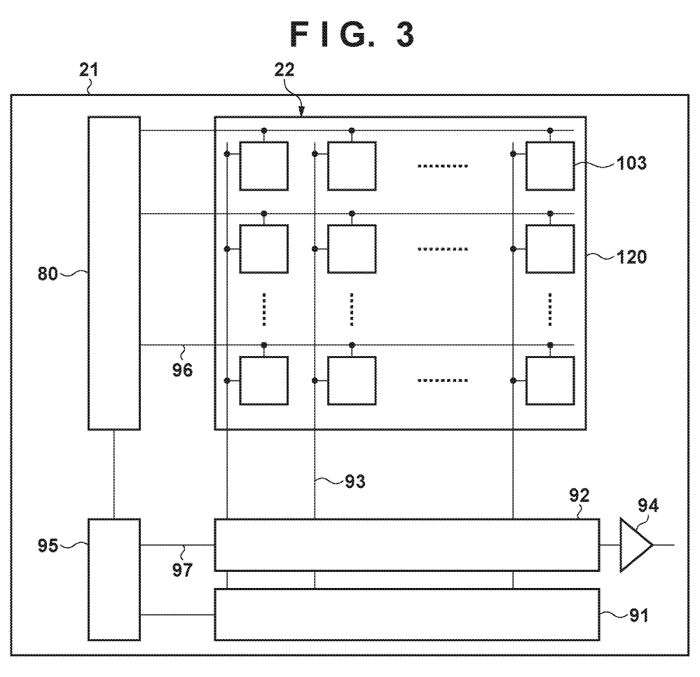

FIG. 3 schematically shows the arrangement of the processing circuit 22 of the second substrate 21. The processing circuit 22 can include, for example, a pixel circuit array 120 including a plurality of pixel circuits 103, a readout circuit 92, a control unit 95, a horizontal scanning circuit 91, a plurality of signal lines 93, a vertical scanning circuit 80, and an output unit 94, or the like. Each pixel circuit 103 constitutes the pixel 101 together with the corresponding photoelectric conversion element 102, and processes a signal output from the photoelectric conversion element 102. One pixel circuit 103 may be provided for one photoelectric conversion element 102, or one pixel circuit 103 may be provided for two or more photoelectric conversion elements 102. In an example, one photoelectric conversion element 102 and one pixel circuit 103 can electrically be connected by a connection portion. The pixel circuit 103 can include, for example, a counter and a memory. The memory can hold a count value obtained by counting by the counter. The photoelectric conversion element array 12 and the pixel circuit array 120 constitute a pixel array.

For example, the vertical scanning circuit 80 can sequentially select a plurality of rows of the photoelectric conversion element array 12 in accordance with a control signal supplied from the control unit 95. The vertical scanning circuit 80 can include, for example, at least one of a shift register and an address decoder. The readout circuit 92 reads out signals output, via the plurality of signal lines 93, from the pixel circuits 103 corresponding to the pixels 101 of the row selected by the vertical scanning circuit 80. For example, the horizontal scanning circuit 91 supplies to the output unit 94, in a predetermined order, the signals for one row read out by the readout circuit 92.

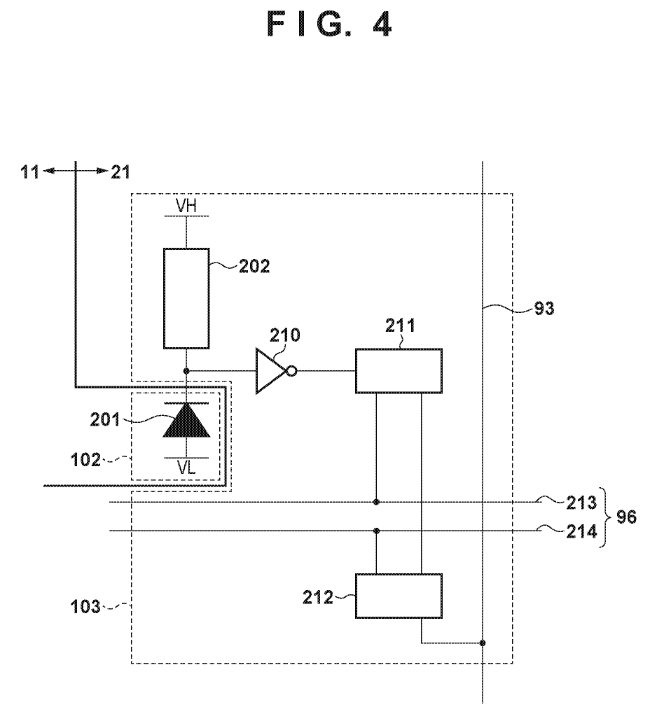

FIG. 4 shows an example of the arrangement of the photoelectric conversion element 102 and the pixel circuit 103. In the example shown in FIG. 4, one pixel circuit 103 is assigned to one photoelectric conversion element 102. The photoelectric conversion element 102 includes an APD 201. At least one of a plurality of components of the pixel circuit 103 may be arranged on the first substrate 11. Alternatively, all the plurality of components of the pixel circuit 103 may be arranged on the first substrate 11.

A first voltage VH can be applied to the cathode of the APD 201. A second voltage VL is applied to the anode of the APD 201, and the first voltage VH has a potential higher than the potential of the second voltage VL. A potential difference between the first voltage VH and the second voltage VL is applied to the APD 201 (between the anode and cathode of the APD 201). This potential difference is a reverse bias voltage that causes the APD 201 to perform an avalanche multiplication operation. Charges generated by photons entering the APD 201 cause avalanche multiplication, thereby generating an avalanche current. A mode of applying a voltage higher than the breakdown voltage of the APD 201 between the anode and cathode of the APD 201 is called a Geiger mode. A mode of applying a voltage around or lower than the breakdown voltage between the anode and cathode of the APD 201 is called a linear mode. An APD operating in the Geiger mode is called an SPAD. In an example, the first voltage VH is 1 V, and the second voltage VL is -30 V.

The pixel circuit 103 can include a quenching element 202 connected between the cathode of the APD 201 and a terminal supplied with the first voltage VH. The quenching element 202 may be understood as an element that supplies the first voltage VH to the cathode of the APD 201. The quenching element 202 has a function of converting the change of the avalanche current generated in the APD 201 into a voltage signal. The quenching element 202 functions as a load circuit (quenching circuit) at the time of signal multiplication by avalanche multiplication, and serves to suppress avalanche multiplication by suppressing the voltage applied to the APD 201. This is known as a quenching operation.

The pixel circuit 103 can additionally include, for example, at least one of a waveform shaping unit 210, a counter circuit 211, and a selection circuit 212. The waveform shaping unit 210 can output a pulse signal by shaping the potential change of the cathode of the APD 201 at the time of detection of a photon. The waveform shaping unit 210 can include, for example, an inverter circuit. In the example shown in FIG. 4, the waveform shaping unit 210 is formed by one inverter, but the waveform shaping unit 210 may be formed by series-connecting a plurality of inverters or by another circuit having the waveform shaping effect.

The counter circuit 211 can be configured to count a pulse signal output from the waveform shaping unit 210 and hold a count value obtained by counting. When a first control pulse of an active level is supplied from the vertical scanning circuit 80 via a driving line 213, the signal held in the counter circuit 211 can be reset. When a second control pulse of an active level is supplied from the vertical scanning circuit 80 via a driving line 214, the selection circuit 212 can electrically connect the counter circuit 211 and the signal line 93. The selection circuit 212 can include, for example, a buffer circuit.

In this example, the counter circuit 211 is provided. However, the photoelectric conversion apparatus 100 may be configured to acquire a pulse detection timing by providing a Time-to-Digital Converter (to be referred to as a TDC hereinafter), instead of the counter circuit 211. In this case, the generation timing of the pulse signal output from the waveform shaping unit 210 can be converted into a digital signal by the TDC. A reference pulse (reference signal) can be supplied from the vertical scanning circuit 80 to the TDC via a driving line to measure the timing of the pulse signal. With reference to the reference pulse, the TDC can generate a digital signal corresponding to the generation timing of the pulse signal output from the waveform shaping unit 210.

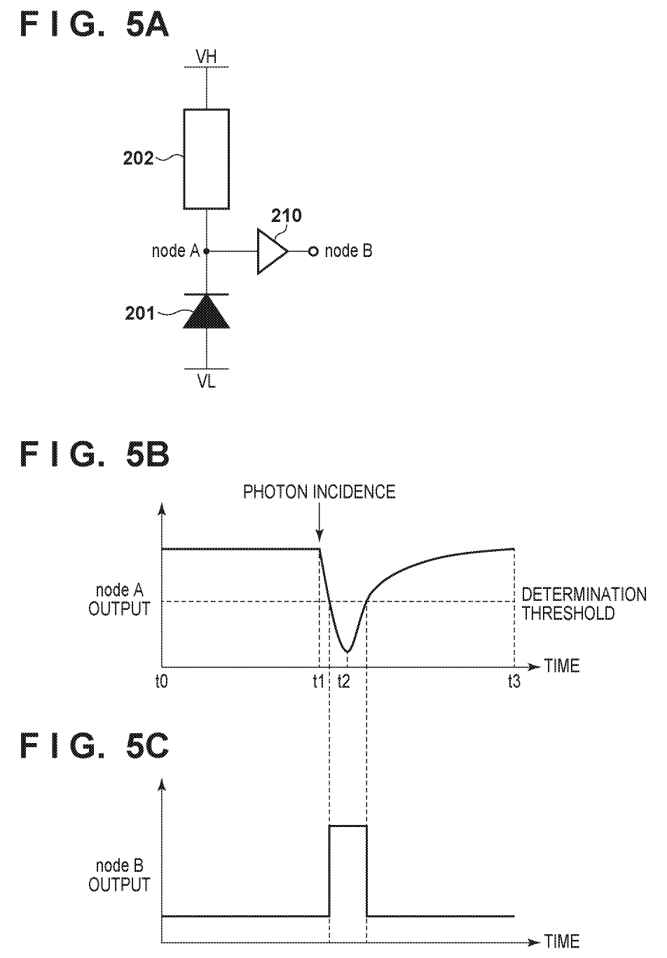

FIGS. 5A to 5C are views for explaining a photon detection operation by the photoelectric conversion apparatus 100. FIG. 5A is a view showing an excerpt of the APD 201, the quenching element 202, and the waveform shaping unit 210 from FIG. 4. The input side of the waveform shaping unit 210 is a node A and the output side of the waveform shaping unit 210 is a node B. FIG. 5B shows the waveform at the node A of FIG. 5A and FIG. 5C shows the waveform at the node B of FIG. 5A. From time t0 to time t1, a potential difference of VH - VL is applied to the APD 201. When a photon enters at time t1, avalanche multiplication occurs in the APD 201. This causes an avalanche multiplication current to flow into the quenching element 202, and the voltage (potential) of the node A drops. When the voltage drop amount increases and the potential difference applied to the APD 201 decreases, the avalanche multiplication of the APD 201 stops. After that, a current compensating for the voltage drop from the voltage VL flows into the node A, and the node A settles at the original potential level at time t3. At this time, a portion at which the output waveform exceeds a given threshold at the node A is waveform-shaped by the waveform shaping unit 210 and a pulse signal appears at the node B.

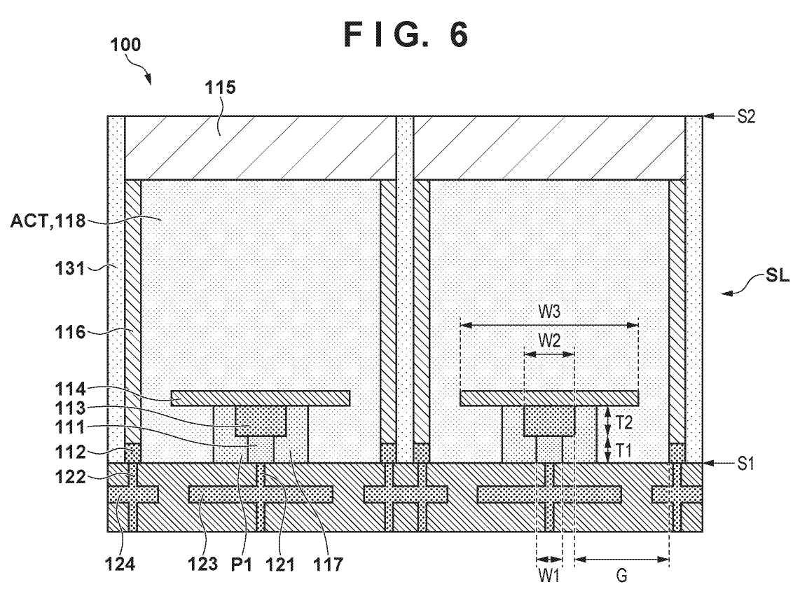

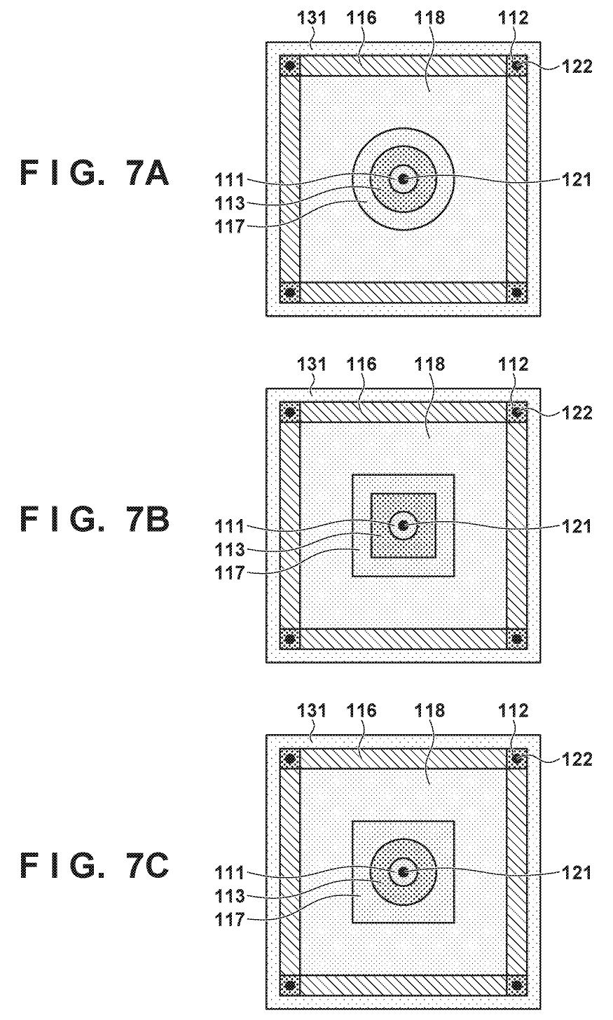

With reference to FIGS. 6 and 7A to 7C, a photoelectric conversion apparatus 100 according to the first embodiment will be described below. FIG. 6 is a sectional view schematically showing the arrangement of two pixels 101 of a plurality of pixels 101 of the photoelectric conversion apparatus 100. FIGS. 7A to 7C are plan views schematically showing three variations of the arrangement of one pixel 101 of the plurality of pixels 101 of the photoelectric conversion apparatus 100.

The photoelectric conversion apparatus 100 includes a semiconductor layer SL including a first surface S1 and a second surface S2. The semiconductor layer SL may be, for example a semiconductor layer of a first substrate 11. The semiconductor layer SL can include a first semiconductor region 111 of the first conductivity type extending from the first surface S1 toward the second surface S2, and a second semiconductor region 113 of the first conductivity type arranged between the first semiconductor region 111 and the second surface S2 so as to contact the first semiconductor region 111. The semiconductor layer SL can also include a third semiconductor region 114 of the second conductivity type arranged between the second semiconductor region 113 and the second surface S2. A strong electric field is generated between the second semiconductor region 113 and the third semiconductor region 114, thereby forming an avalanche multiplication region.

A width W2 of the second semiconductor region 113 in a direction parallel to the first surface S1 is preferably larger than a width W1 of the first semiconductor region 111 in the direction. This arrangement is advantageous for suppressing the strength of the electric field formed in the vicinity of the first surface S1 of the semiconductor layer SL and around the first semiconductor region 111, and this can contribute to lowering the dark count rate (DCR). The width W2 of the second semiconductor region 113 in a direction parallel to the first surface S1 is preferably, for example, two times or more and four times or less of the width W1 of the first semiconductor region 111 in the direction.

The width W2 of the second semiconductor region 113 in a direction parallel to the first surface S1 is preferably smaller than a width W3 of the third semiconductor region 114. This arrangement is advantageous for improving the charge collection effect to the avalanche multiplication region, and this can contribute to suppressing the signal charge count loss.

The semiconductor layer SL can further include a fifth semiconductor region 117 including a portion P1 arranged between the second semiconductor region 113 and the first surface so as to surround the first semiconductor region 111. This arrangement is advantageous for suppressing the strength of the electric field formed in the vicinity of the first surface S1 of the semiconductor layer SL and around the first semiconductor region 111, and this can contribute to lowering the DCR. The impurity concentration of the first conductivity type in the fifth semiconductor region 117 may be lower than the impurity concentration of the first conductivity type in each of the first semiconductor region 111 and the second semiconductor region 113. Here, the fifth semiconductor region 117 can be a semiconductor region of the first conductivity type, an intrinsic semiconductor region, or a semiconductor region of the second conductivity type.

In an example, the first semiconductor region 111 and the second semiconductor region 113 can include a region where the impurity concentration of the first conductivity type is 1 × 10¹⁷ cm⁻³ or more, and the fifth semiconductor region 117 can include a region where the impurity concentration of the first conductivity type is 1 × 10¹⁶ cm⁻³ or less. The width W2 of the second semiconductor region 113 in a direction parallel to the first surface S1 is preferably two times or more of the width W1 of the first semiconductor region 111 in the direction. The width W2 of the second semiconductor region 113 in a direction parallel to the first surface S1 is preferably four times or less of the width of the first semiconductor region 111 in the direction. (W2 - W1) defines the width of the portion P1 arranged between the second semiconductor region 113 and the first surface so as to surround the first semiconductor region 111.

Each pixel 101 can include an active region ACT including the first semiconductor region 111, the second semiconductor region 113, and the third semiconductor region 114. The semiconductor layer SL can include a pixel isolation portion 131 arranged between the pixels 101 adjacent to each other, and a fourth semiconductor region 116 of the second conductivity type arranged between the pixel isolation portion 131 and a sixth semiconductor region 118 (to be described later). The fourth semiconductor region 116 of the second conductivity type can be arranged in contact with the third semiconductor region 114 so as to surround the second semiconductor region 113 and the third semiconductor region 114. The fourth semiconductor region 116 of the second conductivity type can induce charges with majority carrier polarity in the fourth semiconductor region 116. The semiconductor layer SL can include an eighth semiconductor region 112 of the second conductivity type arranged so as to connect the fourth semiconductor region 116 and the first surface S1. The impurity concentration of the second conductivity type in the eighth semiconductor region 112 may be higher than the impurity concentration of the second conductivity type in the fourth semiconductor region 116. The arrangement where the width W2 of the second semiconductor region 113 is larger than the width W1 of the first semiconductor region 111, that is, the arrangement where the width W1 of the first semiconductor region 111 is smaller than the width W2 of the second semiconductor region 113 is advantageous for reducing the strength of the electric field between the first semiconductor region 111 and the fourth semiconductor region 116.

The width W2 of the second semiconductor region 113 in a direction parallel to the first surface S1 is preferably smaller than a spacing G between the second semiconductor region 113 and the pixel isolation portion 131 in the direction. This arrangement is also advantageous for suppressing the strength of the electric field formed in the vicinity of the first surface S1 of the semiconductor layer SL and around the first semiconductor region 111, and this can contribute to lowering the DCR. A dimension T2 of the second semiconductor region 113 in the thickness direction of the semiconductor layer SL (a direction orthogonal to the first surface S1) is preferably, for example, 0.8 times or more and less than 2 times of a dimension T1 of the first semiconductor region 111 in the thickness direction. (T2 - T1) defines the thickness of the portion P1 arranged between the second semiconductor region 113 and the first surface so as to surround the first semiconductor region 111.

The first semiconductor region 111 can function as the cathode of an APD 201, and a first voltage VH can be applied thereto via a first wiring pattern 123 and a first contact 121. The eighth semiconductor region 112 can function as the anode of the APD 201, and a second voltage VL can be applied thereto via a second wiring pattern 124 and a second contact 122.

The semiconductor layer SL can include a seventh semiconductor region 115 of the second conductivity type arranged between the second surface S2 and the third semiconductor region 114. The seventh semiconductor region 115 can be arranged, for example, in contact with the second surface S2. The semiconductor layer SL can also include the sixth semiconductor region 118. In this embodiment, the sixth semiconductor region 118 can be a semiconductor region of the second conductivity type. The sixth semiconductor region 118 can include a portion arranged between the side surface of the fifth semiconductor region 117 and the fourth semiconductor region 116. The sixth semiconductor region 118 can include a portion arranged between the side surface of the third semiconductor region 114 and the fourth semiconductor region 116. The sixth semiconductor region 118 can include a portion arranged between the third semiconductor region 114 and the seventh semiconductor region 115.

In an example shown in FIG. 7A, the first semiconductor region 111 has a circular shape such as a circle in a plan view (an orthogonal projection to the first surface S1), the second semiconductor region 113 has a circular shape such as a circle in the plan view, and the fifth semiconductor region 117 has a circular shape such as a circle in the plan view. In an example shown in FIG. 7B, the first semiconductor region 111 has a circular shape such as a circle in the plan view, the second semiconductor region 113 has a rectangular shape in the plan view, and the fifth semiconductor region 117 has a rectangular shape in the plan view. In an example shown in FIG. 7C, the first semiconductor region 111 has a circular shape such as a circle in the plan view, the second semiconductor region 113 has a circular shape such as a circle in the plan view, and the fifth semiconductor region 117 has a rectangular shape in the plan view.

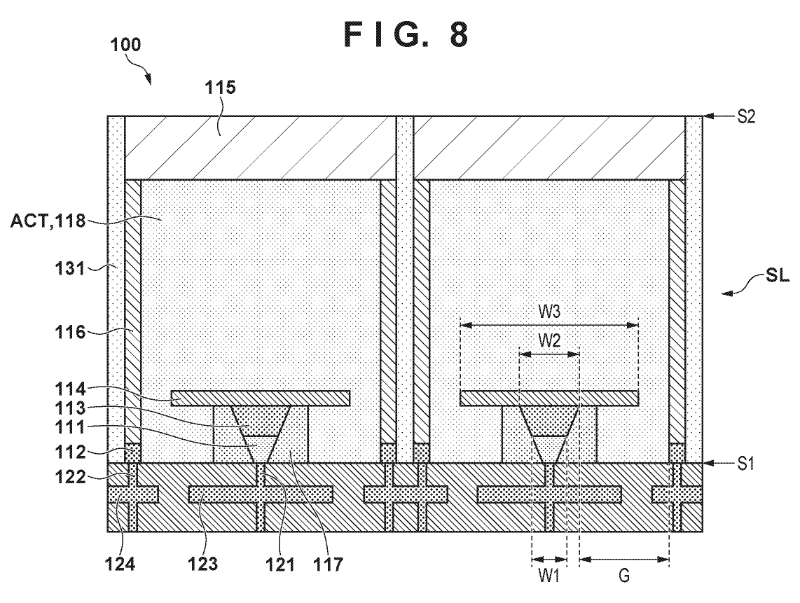

With reference to FIGS. 7A to 7C and 8, a photoelectric conversion apparatus 100 according to the second embodiment will be described. FIG. 8 is a sectional view schematically showing the arrangement of two pixels 101 of a plurality of pixels 101 of the photoelectric conversion apparatus 100 according to the second embodiment. FIGS. 7A to 7C are plan views referenced in the second embodiment to schematically show three variations of the arrangement of one pixel 101 of the plurality of pixels 101 of the photoelectric conversion apparatus 100. Matters not mentioned in the description of the second embodiment can follow the first embodiment.

In the second embodiment, a first semiconductor region 111 and a second semiconductor region 113 include a portion where the width in a direction parallel to a first surface S1 decreases from a second surface S2 toward the first surface S1. From another viewpoint, in the second embodiment, the first semiconductor region 111 and second semiconductor region 113 has a shape where the width in a direction parallel to the first surface S1 decreases from the second surface S2 toward the first surface S1. In the second embodiment, a maximum width W2 of the second semiconductor region 113 in a direction parallel to the first surface S1 is preferably larger than a maximum width W1 of the first semiconductor region 111 in the direction. In the second embodiment, the maximum width W2 of the second semiconductor region 113 in the direction is preferably smaller than a width W3 (or maximum width) of a third semiconductor region 114 in the direction. The maximum width W2 of the second semiconductor region 113 in a direction parallel to the first surface S1 is preferably smaller than a minimum spacing G between the second semiconductor region 113 and a pixel isolation portion 131 in the direction.

Note that in the first embodiment as well, W1, W2, and W3 may be specified as the maximum widths of the first semiconductor region 111, the second semiconductor region 113, and the third semiconductor region 114, respectively, in a direction parallel to the first surface S1. In the first embodiment as well, G may be specified as the minimum spacing between the second semiconductor region 113 and the pixel isolation portion 131 in a direction parallel to the first surface S1.

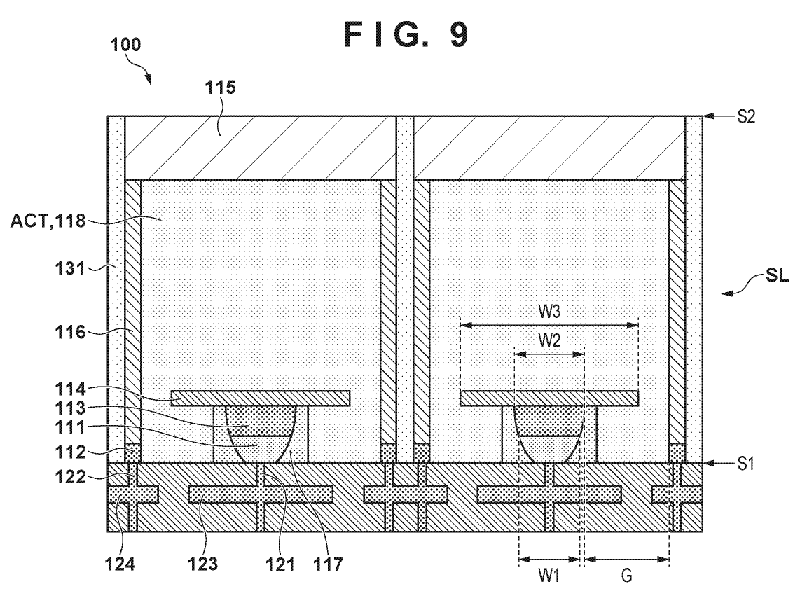

With reference to FIGS. 7A to 7C and 9, a photoelectric conversion apparatus 100 according to the third embodiment will be described. FIG. 9 is a sectional view schematically showing the arrangement of two pixels 101 of a plurality of pixels 101 of the photoelectric conversion apparatus 100 according to the third embodiment. FIGS. 7A to 7C are plan views referenced in the third embodiment to schematically show three variations of the arrangement of one pixel 101 of the plurality of pixels 101 of the photoelectric conversion apparatus 100. Matters not mentioned in the description of the third embodiment can follow the second embodiment. In the third embodiment, a first semiconductor region 111 and a second semiconductor region 113 include a portion where the width in a direction parallel to a first surface S1 decreases toward the first surface S1. From another viewpoint, in the third embodiment, the first semiconductor region 111 and second semiconductor region 113 have a shape where the width in a direction parallel to the first surface S1 decreases toward the first surface S1.

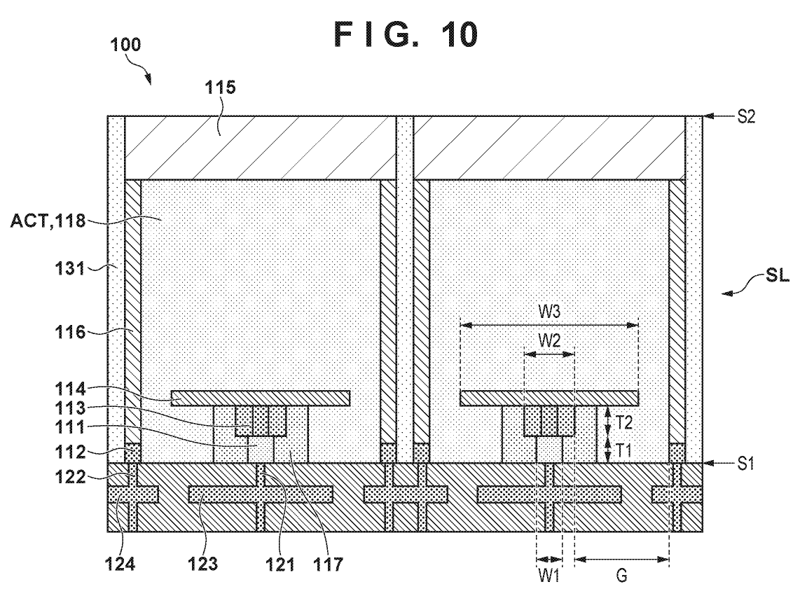

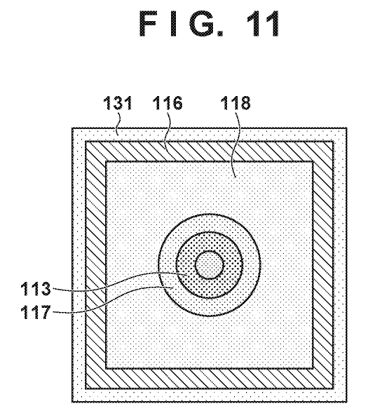

With reference to FIGS. 10 and 11, a photoelectric conversion apparatus 100 according to the fourth embodiment will be described. FIG. 10 is a sectional view schematically showing the arrangement of two pixels 101 of a plurality of pixels 101 of the photoelectric conversion apparatus 100 according to the fourth embodiment. FIG. 11 is a plan view schematically showing the arrangement of one pixel 101 of the plurality of pixels 101 of the photoelectric conversion apparatus 100 according to the fourth embodiment. Matters not mentioned in the description of the fourth embodiment can follow the first to third embodiments. In the fourth embodiment, a second semiconductor region 113 has a ring shape. The region surrounded by the second semiconductor region 113 may have the same conductivity type and impurity concentration as a fifth semiconductor region 117, or may have the conductivity type and/or impurity concentration different from that of the fifth semiconductor region 117.

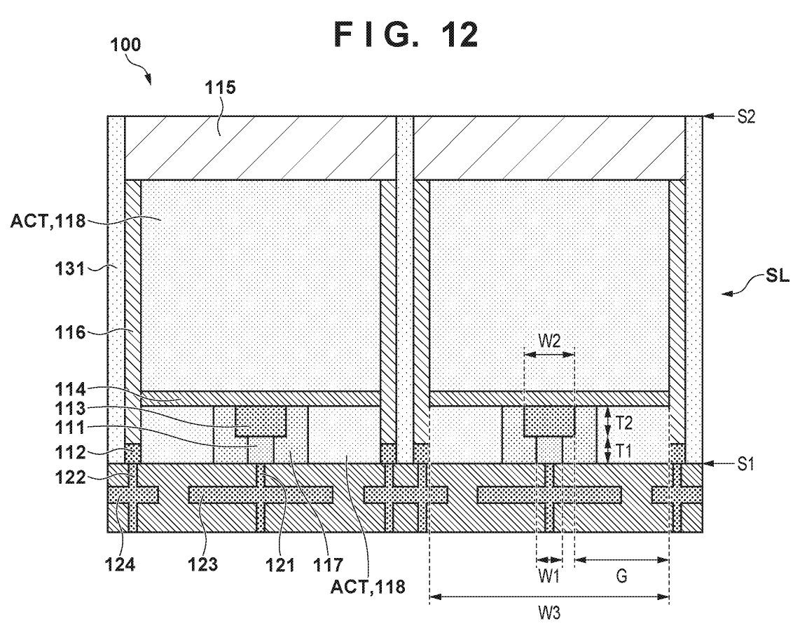

With reference to FIG. 12, a photoelectric conversion apparatus 100 according to the fifth embodiment will be described. FIG. 12 is a sectional view schematically showing the arrangement of two pixels 101 of a plurality of pixels 101 of the photoelectric conversion apparatus 100 according to the fifth embodiment. Matters not mentioned in the description of the fifth embodiment can follow the first to fourth embodiments. In the fifth embodiment, a third semiconductor region 114 extends so as to contact a fourth semiconductor region 116. This arrangement can contribute to improvement of charge collection efficiency.

In the fifth embodiment, a sixth semiconductor region 118 may be, for example, a semiconductor region of the first conductivity type, a semiconductor region of the second conductivity type, or an intrinsic semiconductor region. The sixth semiconductor region 118 can include a portion arranged between the side surface of a fifth semiconductor region 117 and the fourth semiconductor region 116. The sixth semiconductor region 118 can include a portion arranged between the side surface of the third semiconductor region 114 and the fourth semiconductor region 116. The sixth semiconductor region 118 can include a portion arranged between the third semiconductor region 114 and a seventh semiconductor region 115.

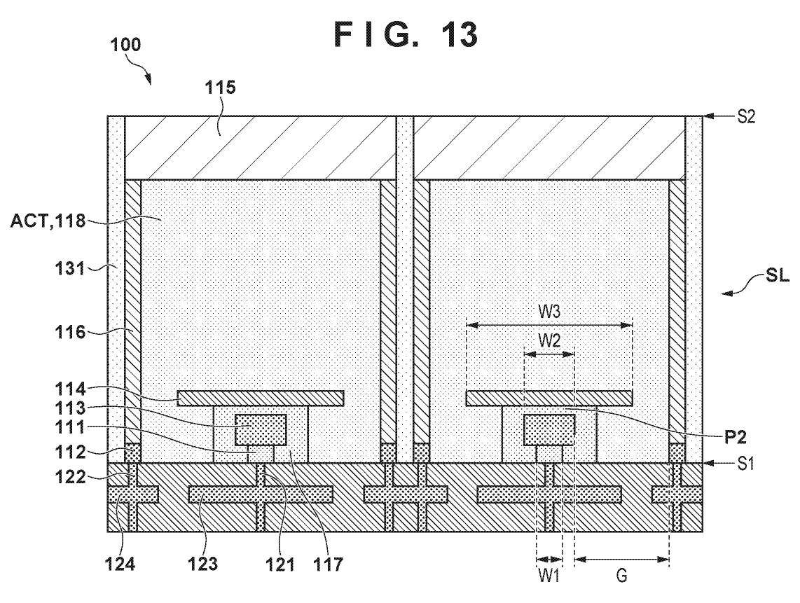

With reference to FIG. 13, a photoelectric conversion apparatus 100 according to the sixth embodiment will be described. FIG. 13 is a sectional view schematically showing the arrangement of two pixels 101 of a plurality of pixels 101 of the photoelectric conversion apparatus 100 according to the sixth embodiment. Matters not mentioned in the description of the sixth embodiment can follow the first to fifth embodiments. For example, in the sixth embodiment, a third semiconductor region 114 may extend so as to contact a fourth semiconductor region 116 as shown in FIG. 12. In the sixth embodiment, a fifth semiconductor region 117 includes a portion P2 arranged between a second semiconductor region 113 and the third semiconductor region 114. From another viewpoint, the entire periphery of the second semiconductor region 113 can be surrounded by a first semiconductor region 111 and the fifth semiconductor region 117. The fifth semiconductor region 117 is advantageous for relaxing the electric field around the second semiconductor region 113. The fifth semiconductor region 117 is, for example, a region where the impurity concentration of the first conductivity type is 1 × 10¹⁶ cm⁻³ or less.

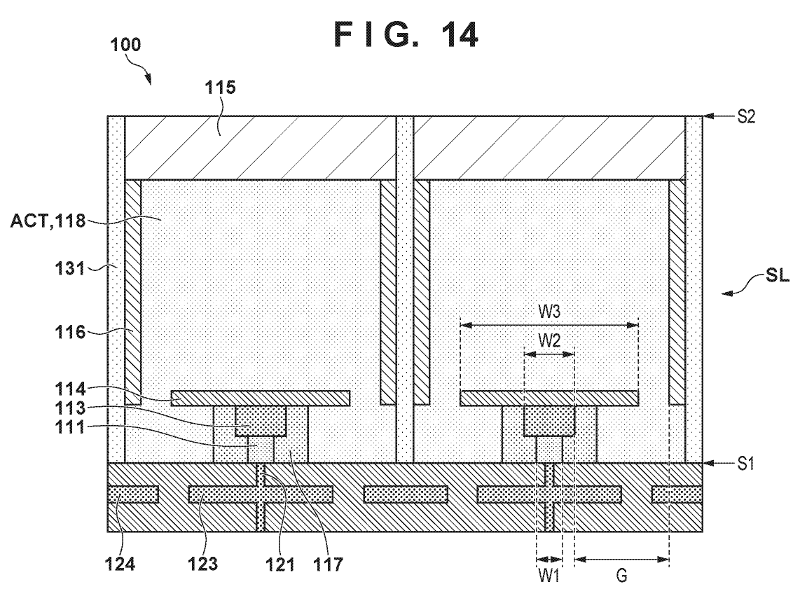

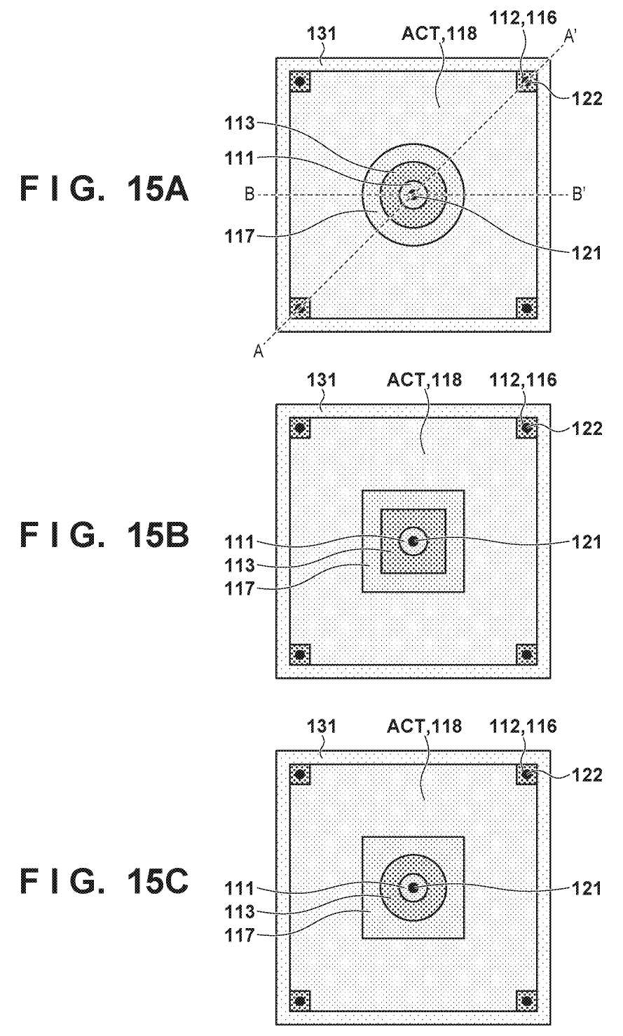

With reference to FIGS. 6, 14, and FIG. 15A to FIG. 15C, a photoelectric conversion apparatus 100 according to the seventh embodiment will be described. FIG. 14 is a sectional view schematically showing the arrangement of each of two pixels 101 of a plurality of pixels 101 of the photoelectric conversion apparatus 100 according to the seventh embodiment, taken along a line B - B' in FIG. 15A. FIG. 6 is a sectional view referenced in the seventh embodiment to schematically show the arrangement of each of two pixels 101 of the plurality of pixels 101 of the photoelectric conversion apparatus 100 according to the seventh embodiment, taken along a line A - A' in FIG. 15A. FIGS. 15A to 15C are plan views schematically showing three variations of the arrangement of one pixel 101 of the plurality of pixels 101 of the photoelectric conversion apparatus 100. Matters not mentioned in the description of the seventh embodiment can follow the first to sixth embodiments. For example, in the seventh embodiment, a third semiconductor region 114 may extend so as to contact a fourth semiconductor region 116 as shown in FIG. 12.

In the seventh embodiment, the fourth semiconductor region 116 can be arranged so as not to surround a first semiconductor region 111. Alternatively, in the seventh embodiment, the fourth semiconductor region 116 can be arranged so as not to surround the first semiconductor region 111 and a second semiconductor region 113.

From another viewpoint, an eighth semiconductor region 112 can be arranged at a position farthest from the first semiconductor region 111 in a region on the side of the first semiconductor region 111 in an active region ACT. Alternatively, the eighth semiconductor region 112 can be arranged at a position farthest from the first semiconductor region 111 in a region on the side of the first semiconductor region 111 and the second semiconductor region 113 in the active region ACT.

From still another viewpoint, the eighth semiconductor region 112 can be arranged in the corner portion of the active region ACT. Alternatively, the plurality of pixels 101 can be arranged to form a rectangular lattice, and the eighth semiconductor region 112 can be arranged in the diagonal direction of the rectangular lattice when viewed from the first semiconductor region 111.

The eighth semiconductor region 112 can be arranged between the fourth semiconductor region 116 and a first surface S1. The eighth semiconductor region 112 can function as the anode of an APD 201, and a second voltage VL can be applied thereto via a second wiring pattern 124 and a second contact 122. Along a line B - B' in FIG. 15A, a part of a sixth semiconductor region 118 is arranged between the fourth semiconductor region 116 and the first surface S1.

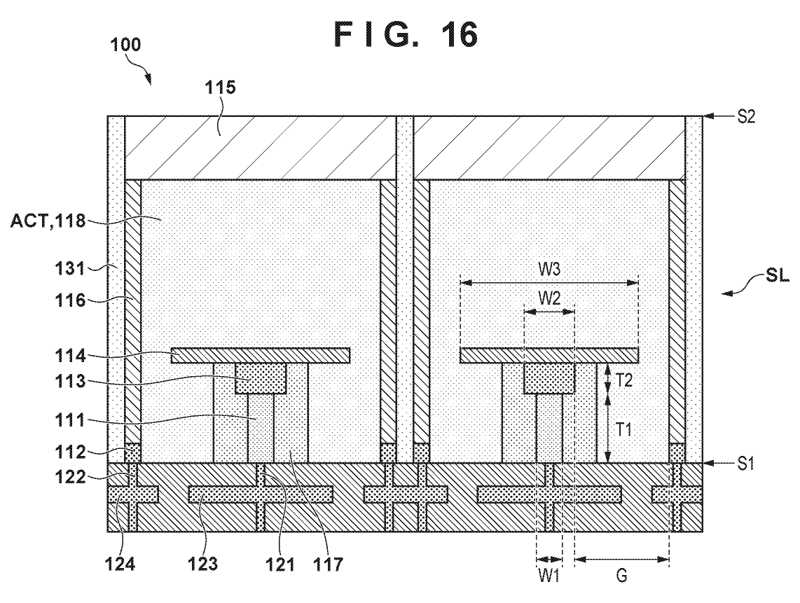

With reference to FIGS. 7A to 7C and 16, a photoelectric conversion apparatus 100 according to the eighth embodiment will be described. FIG. 16 is a sectional view schematically showing the arrangement of two pixels 101 of a plurality of pixels 101 of the photoelectric conversion apparatus 100 according to the eighth embodiment. FIGS. 7A to 7C are plan views referenced in the eighth embodiment to schematically show three variations of the arrangement of one pixel 101 of the plurality of pixels 101 of the photoelectric conversion apparatus 100. Matters not mentioned in the description of the eighth embodiment can follow the first to seventh embodiments. For example, in the eighth embodiment, a third semiconductor region 114 may extend so as to contact a fourth semiconductor region 116 as shown in FIG. 12.

The eighth embodiment focuses on the relationship between a dimension T1 of a first semiconductor region 111 and a dimension T2 of a second semiconductor region 113 in the thickness direction of a semiconductor layer SL (a direction orthogonal to a first surface S1). The dimension T2 is preferably 0.8 times or more and less than two times of the dimension T1, and more preferably 1 time or more and less than 2 times of the dimension T1.

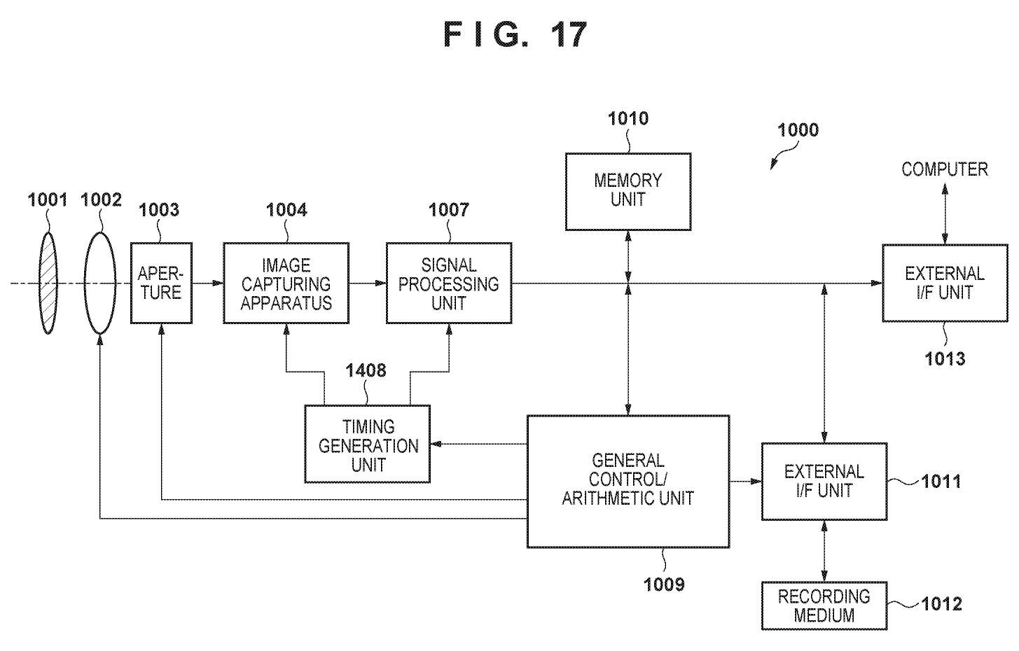

With reference to FIG. 17, a photoelectric conversion system according to the first application example will be described below. FIG. 17 is a block diagram showing the schematic configuration of a photoelectric conversion system according to the first application example.

The above-described photoelectric conversion apparatus 100 is applicable to various kinds of photoelectric conversion systems. Examples of photoelectric conversion systems to which the photoelectric conversion apparatus is applicable are a digital still camera, a digital camcorder, a monitoring camera, a copying machine, a facsimile apparatus, a mobile phone, an in-vehicle camera, and an observation satellite. A camera module including an optical system such as a lens and an image capturing apparatus is also included in the photoelectric conversion systems. FIG. 17 exemplarily shows the block diagram of a digital still camera as an example of these.

A photoelectric conversion system 1000 exemplarily shown in FIG. 17 includes an image capturing apparatus 1004 as an example of the photoelectric conversion apparatus. The photoelectric conversion system 1000 also includes a lens 1002 that forms an optical image of an object on the image capturing apparatus 1004, an aperture 1003 configured to change the amount of light passing through the lens 1002, and a barrier 1001 configured to protect the lens 1002. The lens 1002 and the aperture 1003 form an optical system (optical apparatus) that condenses light to the image capturing apparatus 1004. The image capturing apparatus 1004 is the photoelectric conversion apparatus 100 (image capturing apparatus) according to one of the above-described embodiments, and converts the optical image formed by the lens 1002 into an electrical signal.

The photoelectric conversion system 1000 also includes a signal processing unit 1007 that is an image generation unit configured to generate an image by processing an output signal output from the image capturing apparatus 1004. The signal processing unit 1007 functions as a processing apparatus that performs an operation of performing various kinds of correction and compression as needed, thereby outputting image data. The signal processing unit 1007 may be formed on a semiconductor substrate on which the image capturing apparatus 1004 is provided or may be formed on a semiconductor substrate different from the image capturing apparatus 1004. In addition, the image capturing apparatus 1004 and the signal processing unit 1007 may be formed on the same semiconductor substrate.

The photoelectric conversion system 1000 further includes a memory unit 1010 configured to temporarily store image data, and an external interface unit (external I/F unit) 1013 configured to communicate with an external computer or the like. Furthermore, the photoelectric conversion system 1000 includes a recording medium 1012 such as a semiconductor memory configured to record or read out image capturing data, and a recording medium control I/F unit 1011 configured to perform record or readout for the recording medium 1012. The recording medium control I/F unit 1011 and the recording medium 1012 can form a part of a recording apparatus. Note that the recording medium 1012 may be incorporated in the photoelectric conversion system 1000 or may be detachable.

Furthermore, the photoelectric conversion system 1000 includes a general control/arithmetic unit 1009 that controls various kinds of operations and the entire digital still camera, and a timing generation unit 1408 that outputs various kinds of timing signals to the image capturing apparatus 1004 and the signal processing unit 1007. The general control/arithmetic unit 1009 and the timing generation unit 1408 can form a part of a control apparatus configured to control an operation of the photoelectric conversion system 1000. In this example, the timing signal and the like may be input from the outside, and the photoelectric conversion system 1000 need only include at least the image capturing apparatus 1004, and the signal processing unit 1007 that processes an output signal output from the image capturing apparatus 1004.

The image capturing apparatus 1004 outputs an image capturing signal to the signal processing unit 1007. The signal processing unit 1007 executes predetermined signal processing for the image capturing signal output from the image capturing apparatus 1004, and outputs image data. The signal processing unit 1007 generates an image using the image capturing signal. Although not shown in FIG. 17, a display apparatus such as a display for displaying the generated image may be arranged in the photoelectric conversion system 1000. As described above, according to this application example, it is possible to implement the photoelectric conversion system 1000 to which the photoelectric conversion apparatus 100 (image capturing apparatus) according to one of the above-described embodiments is applied.

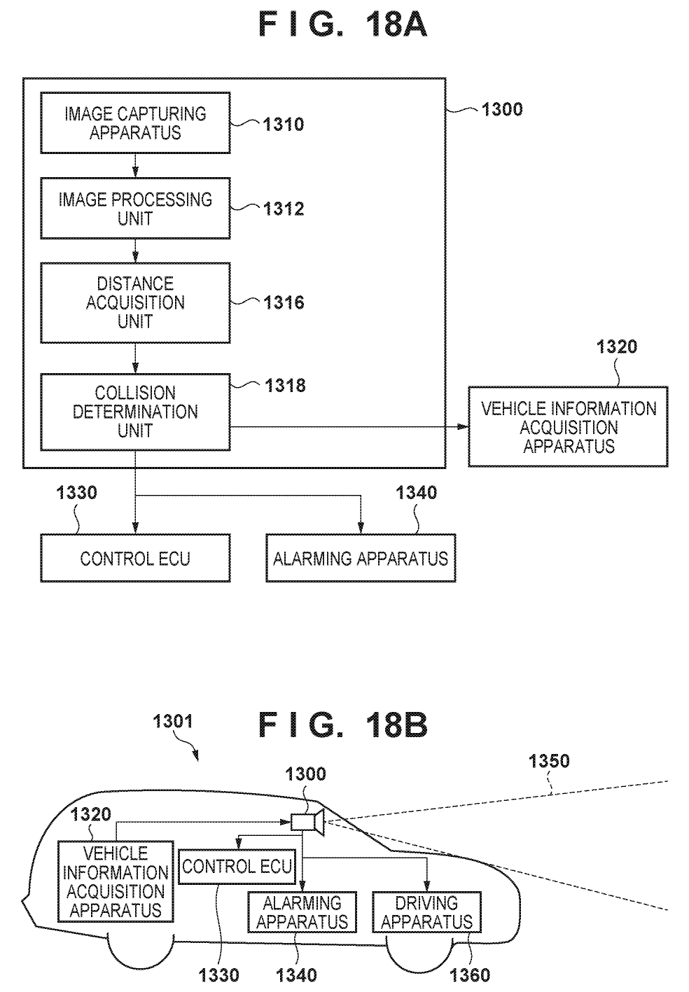

A photoelectric conversion system 1300 and a moving body 1301 according to the second application example will be described with reference to FIGS. 18A and 18B. FIGS. 18A and 18B are views showing the arrangement of the photoelectric conversion system 1300 and the moving body 1301 according to the second application example.

FIG. 18A shows an example of a photoelectric conversion system concerning an in-vehicle camera. The photoelectric conversion system 1300 includes an image capturing apparatus 1310. The image capturing apparatus 1310 is the photoelectric conversion apparatus 100 (image capturing apparatus) described in one of the above-described embodiments. The photoelectric conversion system 1300 includes an image processing unit 1312 that performs image processing for a plurality of image data acquired by the image capturing apparatus 1310. The photoelectric conversion system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using Time of Flight (ToF) method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by a Field Programmable Gate Array (FPGA), Application Specific Integrated Circuit (ASIC), or the like. Alternatively, the distance acquisition unit 1316 may be implemented by a combination of these.

The photoelectric conversion system 1300 is connected to a vehicle information acquisition apparatus 1320, and can acquire vehicle information such as a vehicle speed, a yaw rate, and a steering angle. The photoelectric conversion system 1300 is also connected to an ECU 1330 that is a control apparatus configured to output a control signal for generating a braking force to the vehicle based on the determination result of the collision determination unit 1318. Furthermore, the photoelectric conversion system 1300 is connected to an alarm apparatus 1340 that generates an alarm to the driver based on the determination result of the collision determination unit 1318. For example, if collision possibility is high as the determination result of the collision determination unit 1318, the ECU 1330 controls a driving apparatus (machine apparatus) 1360 to perform braking, releasing the accelerator pedal, or suppressing the engine output, thereby controlling the vehicle for avoiding collision and reducing damage. The alarm apparatus 1340 sounds an alarm, displays alarm information on the screen of a car navigation system or the like, or applies a vibration to the seat belt or a steering wheel, thereby making an alarm to the user.

In this application example, the periphery of the vehicle (moving body 1301), for example, the front or rear side is captured by the photoelectric conversion system 1300. FIG. 18B shows the photoelectric conversion system when capturing the front side (image capturing range 1350) of the vehicle. The vehicle information acquisition apparatus 1320 sends an instruction to the photoelectric conversion system 1300 or the image capturing apparatus 1310. With this configuration, it is possible to further improve the accuracy of distance measurement.

An example in which control is executed so as not to collide with another vehicle has been explained above. The photoelectric conversion system 1300 can also be applied to control of performing automated driving following another vehicle or control of performing automated driving without deviating from a lane. Furthermore, the photoelectric conversion system 1300 can be applied not only to a vehicle such as an automobile but also to, for example, a moving body (moving apparatus) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, a propeller of a moving body, or the like. In addition, the photoelectric conversion system can be applied not only to a moving body but also to equipment that broadly uses object recognition, such as an intelligent transport system (ITS).

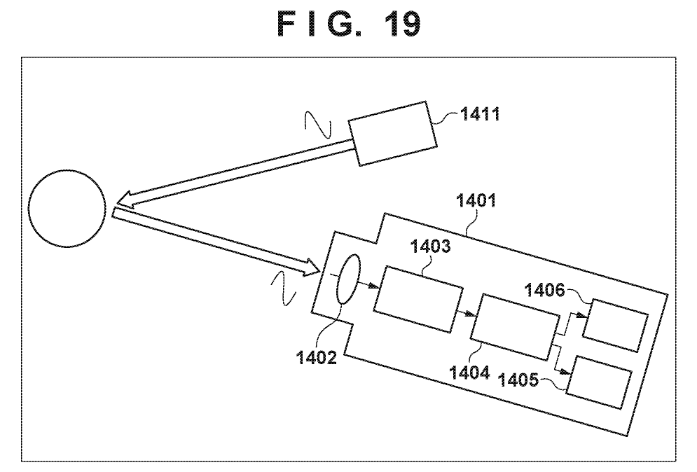

A photoelectric conversion system according to the third application example will be described with reference to FIG. 19. FIG. 19 is a block diagram showing an example of the arrangement of a distance image sensor 1401 as the photoelectric conversion system according to this embodiment.

As shown in FIG. 19, the distance image sensor 1401 includes an optical system 1402, a photoelectric conversion apparatus 1403, an image processing circuit 1404, a monitor 1405, and a memory 1406. Then, the distance image sensor 1401 can receive light (modulated light or pulsed light) projected from a light source apparatus 1411 toward an object and reflected by the surface of the object, thereby acquiring a distance image corresponding to the distance up to the object.

The optical system 1402 is formed by including one or a plurality of lenses, and guides image light (incident light) from the object to the photoelectric conversion apparatus 1403 and forms an image on the light-receiving surface (sensor portion) of the photoelectric conversion apparatus 1403.

As the photoelectric conversion apparatus 1403, the photoelectric conversion apparatus 100 of each of the above-described embodiments is applied, and a distance signal indicating a distance obtained from a light reception signal output from the photoelectric conversion apparatus 1403 is supplied to the image processing circuit 1404.

The image processing circuit 1404 performs image processing of creating a distance image based on the distance signal supplied from the photoelectric conversion apparatus 1403. Then, the distance image (image data) obtained by the image processing is supplied to and displayed on the monitor 1405, and supplied to and stored (recorded) in the memory 1406.

The distance image sensor 1401 having such arrangement can acquire, for example, a more correct distance image along with improvement in characteristic of pixels by applying the above-described photoelectric conversion apparatus 100.

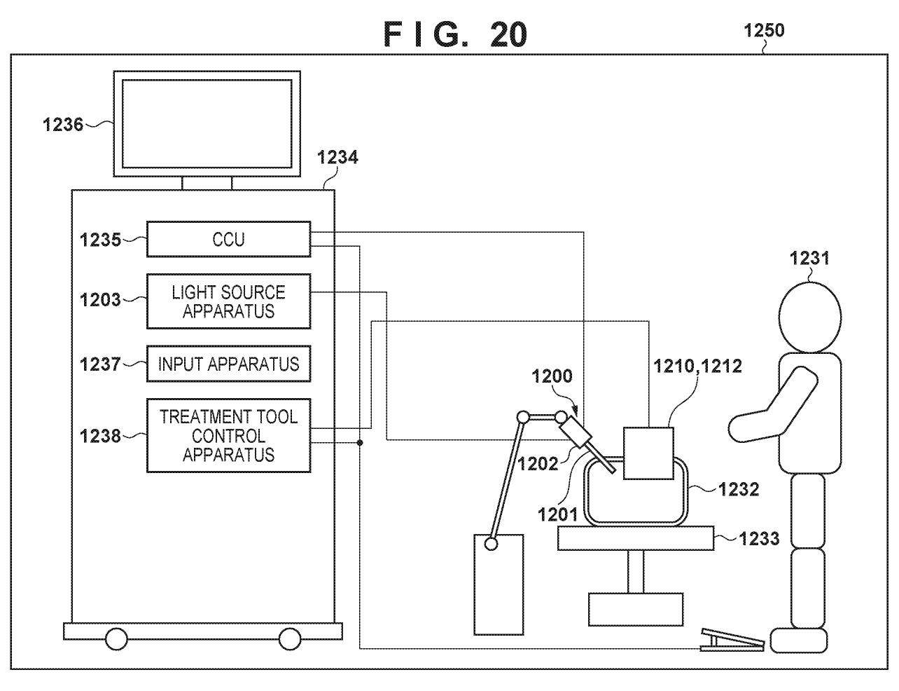

A photoelectric conversion system according to the fourth application example will be described with reference to FIG. 20. FIG. 20 is a view showing an example of the schematic arrangement of an endoscopic surgery system 1250 as the photoelectric conversion system according to fourth application example.

FIG. 20 shows a state in which an operator (doctor) 1231 operates on a patient 1232 on a patient bed 1233 using the endoscopic surgery system 1250. As shown in FIG. 20, the endoscopic surgery system 1250 is formed from an endoscope 1200, a surgical tool 1210, and a cart 1234 on which various apparatuses for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 20, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source apparatus 1203 is connected to the endoscope 1200, and light generated by the light source apparatus 1203 is guided to the distal end of the lens barrel by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion apparatus are provided in the camera head 1202, and reflected light (observation light) from the observation target is condensed by the optical system to the photoelectric conversion apparatus. The observation light is photoelectrically converted by the photoelectric conversion apparatus to generate an electrical signal corresponding to the observation light, that is, an image signal corresponding to an observation image. As the photoelectric conversion apparatus, the photoelectric conversion apparatus 100 (image capturing apparatus) described in each of the above-described embodiments can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display apparatus 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display apparatus 1236 displays the image based on the image signal having undergone the image processing by the CCU 1235.

The light source apparatus 1203 is formed from a light source such as a Light Emitting Diode (LED), and supplies, to the endoscope 1200, irradiation light at the time of imaging an operation portion or the like.

An input apparatus 1237 is an input interface to the endoscopic surgery system 1250. The user can input various kinds of information or instructions to the endoscopic surgery system 1250 via the input apparatus 1237.

A treatment tool control apparatus 1238 controls driving of an energy treatment tool 1212 for ablation or incision of the tissue, sealing of a blood vessel, or the like.

The light source apparatus 1203 that supplies, to the endoscope 1200, irradiation light at the time of imaging an operation portion can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source apparatus 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source apparatus 1203 may be controlled to change the intensity of light to be output for every predetermined time. It is possible to time-divisionally acquire images by controlling driving of the image sensor of the camera head 1202 in synchronism with the timing of changing the intensity of the light, and combine the images, thereby generating an image of a high dynamic range without so-called shadow detail loss or highlight detail loss.

The light source apparatus 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing radiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source apparatus 1203 can be configured to supply narrow band light and/or excitation light corresponding to such special light observation.

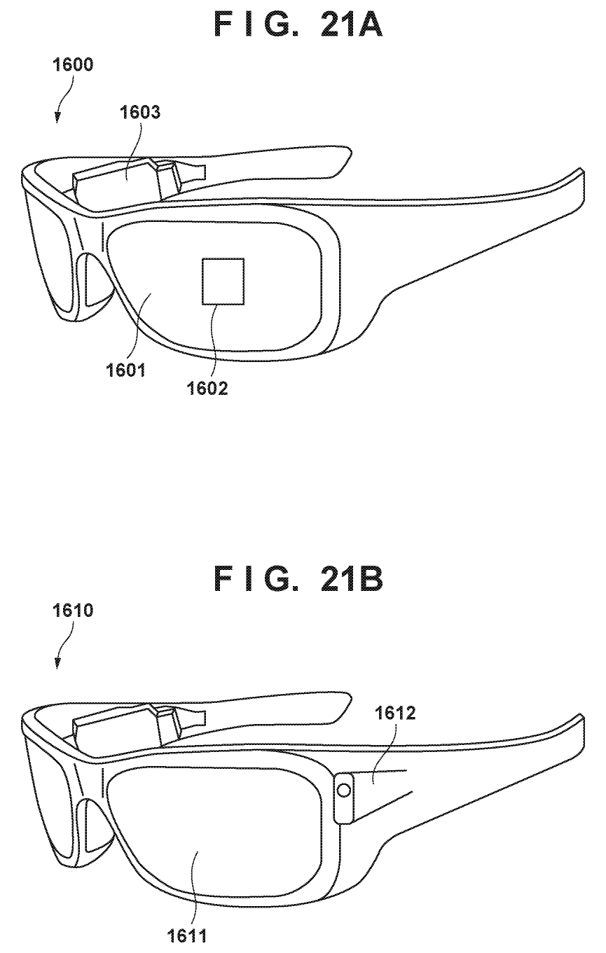

A photoelectric conversion system according to the fifth application example will be described with reference to FIGS. 21A and 21B. FIG. 21A describes glasses 1600 (smartglasses) as the photoelectric conversion system according to the fifth application example. The glasses 1600 include a photoelectric conversion apparatus 1602. The photoelectric conversion apparatus 1602 is the photoelectric conversion apparatus 100 (image capturing apparatus) described in each of the above embodiments. A display apparatus including the light emitting apparatus such as an OLED or LED may be provided on the back surface side of a lens 1601. One or a plurality of photoelectric conversion apparatuses 1602 may be provided. Alternatively, a plurality of kinds of photoelectric conversion apparatuses may be used in combination. The arrangement position of the photoelectric conversion apparatus 1602 is not limited to that shown in FIG. 21A.

The glasses 1600 further include a control apparatus 1603. The control apparatus 1603 functions as a power supply that supplies electric power to the photoelectric conversion apparatus 1602 and the above-described display apparatus. In addition, the control apparatus 1603 controls the operations of the photoelectric conversion apparatus 1602 and the display apparatus. An optical system configured to condense light to the photoelectric conversion apparatus 1602 is formed on the lens 1601.

FIG. 21B describes glasses 1610 (smartglasses) according to an application example. The glasses 1610 include a control apparatus 1612, and a photoelectric conversion apparatus corresponding to the photoelectric conversion apparatus 1602 and a display apparatus are mounted on the control apparatus 1612. The photoelectric conversion apparatus in the control apparatus 1612 and an optical system configured to project light emitted from the display apparatus are formed in a lens 1611, and an image is projected to the lens 1611. The control apparatus 1612 functions as a power supply that supplies electric power to the photoelectric conversion apparatus and the display apparatus, and controls the operations of the photoelectric conversion apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus according to this application example can include a photoelectric conversion apparatus including a light receiving element, and control a displayed image of the display apparatus based on the line-of-sight information of the user from the photoelectric conversion apparatus.

More specifically, the display apparatus decides a first visual field region at which the user is gazing and a second visual field region other than the first visual field region based on the line-of-sight information. The first visual field region and the second visual field region may be decided by the control apparatus of the display apparatus, or those decided by an external control apparatus may be received. In the display region of the display apparatus, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object ahead of the line of sight from the image of the eyeball using the image of the eyeball and the direction of actual viewing of the eyeball in the image as supervised data. The AI program may be held by the display apparatus, the photoelectric conversion apparatus, or an external apparatus. If the external apparatus holds the AI program, it is transmitted to the display apparatus via communication.

When performing display control based on line-of-sight detection, smartglasses further including a photoelectric conversion apparatus configured to capture the image of the outside can preferably be applied. The smartglasses can display the captured outside image information in real time.

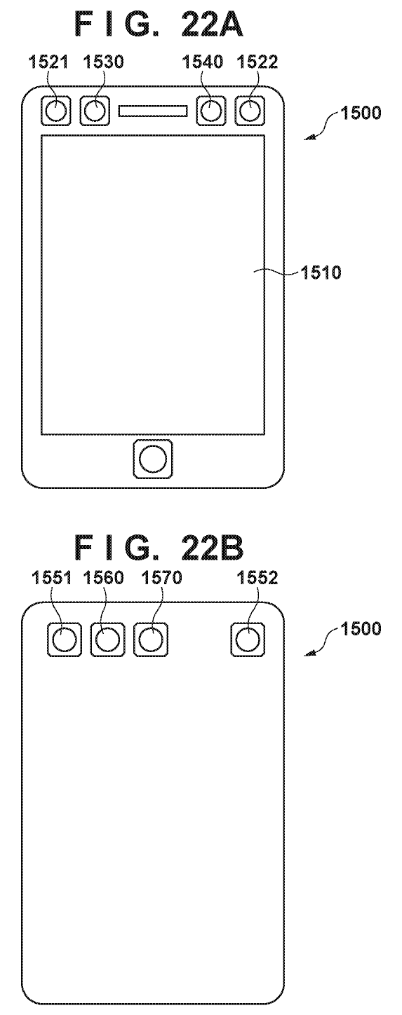

The sixth application example will be described with reference to FIGS. 22A and 22B. The above-described photoelectric conversion apparatus and photoelectric conversion system may be applied to, for example, electronic equipment such as a so-called smartphone or tablet.

FIGS. 22A and 22B are views showing an example of electronic equipment 1500 on which the photoelectric conversion apparatus is mounted. FIG. 22A shows the front surface side of the electronic equipment 1500, and FIG. 22B shows the back surface side of the electronic equipment 1500.

As shown FIG. 22A, a display 1510 that displays an image is arranged at the center of the front surface of the electronic equipment 1500. Then, front cameras 1521 and 1522 for each of which the above-described photoelectric conversion apparatus 100 is used, an IR light source 1530 that emits infrared rays, and a visible light source 1540 that emits visible light are arranged along the upper side of the front surface of the electronic equipment 1500.

As shown in FIG. 22B, rear cameras 1551 and 1552 for each of which the above-described photoelectric conversion apparatus 100 is used, an IR light source 1560 that emits infrared rays, and a visible light source 1570 that emits visible light are arranged along the upper side of the back surface of the electronic equipment 1500.

By applying the above-described photoelectric conversion apparatus 100, the electronic equipment 1500 having the above arrangement can capture, for example, an image of higher quality. Note that the photoelectric conversion apparatus can be applied to electronic equipment such as an infrared sensor, a distance measurement sensor using an active infrared source, a security camera, or a personal or biometric authentication camera. This can improve the accuracy and performance of the electronic equipment.

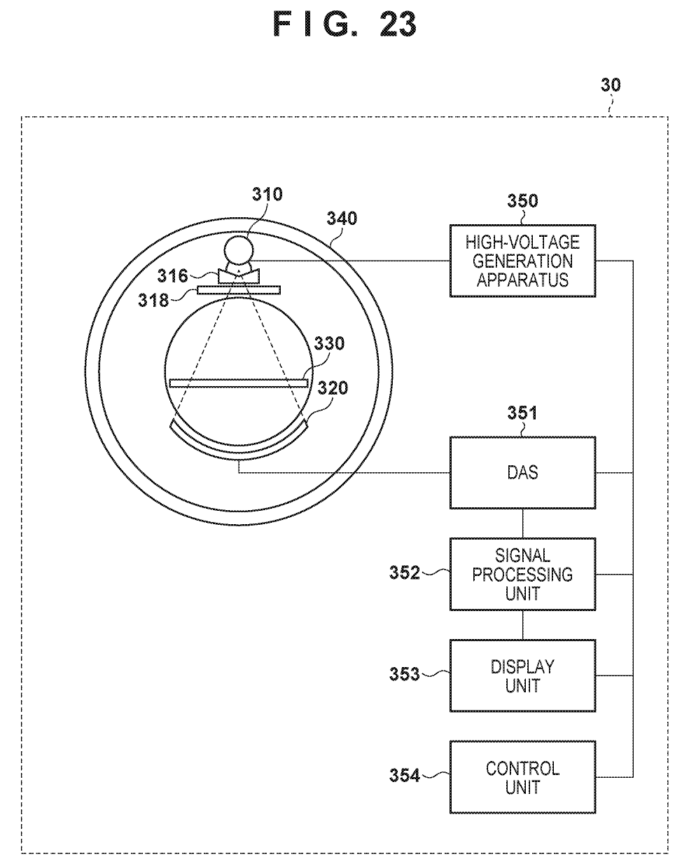

FIG. 23 is a block diagram of an X-ray CT apparatus according to the seventh application example. The above-described photoelectric conversion apparatus 100 is applicable to a detector of the X-ray CT apparatus. An X-ray CT apparatus 30 according to this application example includes an X-ray generation unit 310, a wedge 316, a collimator 318, an X-ray detection unit 320, a top plate 330, a rotating frame 340, and a high-voltage generation apparatus 350. The X-ray CT apparatus 30 also includes a Data Acquisition System (DAS) 351, a signal processing unit 352, a display unit 353, and a control unit 354.

The X-ray generation unit 310 is formed from, for example, a vacuum tube that generates X-rays. The vacuum tube of the X-ray generation unit 310 is supplied with a filament current and a high voltage from the high-voltage generation apparatus 350. When thermoelectrons are emitted from a cathode (filament) to an anode (target), X-rays are generated.

The wedge 316 is a filter that adjusts the amount of X-rays emitted from the X-ray generation unit 310. The wedge 316 attenuates the amount of X-rays so that the X-rays emitted from the X-ray generation unit 310 to an object have a predetermined distribution. The collimator 318 is formed from a lead plate or the like that narrows the irradiation range of the X-rays having passed through the wedge 316. The X-rays generated by the X-ray generation unit 310 is formed in a cone beam shape via the collimator 318, and the object on the top plate 330 is irradiated with the X-rays.

The X-ray detection unit 320 is formed using the above-described photoelectric conversion apparatus 100. The X-ray detection unit 320 detects the X-rays having passed through the object from the X-ray generation unit 310, and outputs a signal corresponding to the amount of the X-rays to the DAS 351.

The rotating frame 340 is annular, and is configured to be rotatable. The X-ray generation unit 310 (the wedge 316 and the collimator 318) and the X-ray detection unit 320 are arranged to face each other in the rotating frame 340. The X-ray generation unit 310 and the X-ray detection unit 320 can rotate together with the rotating frame 340.

The high-voltage generation apparatus 350 includes a boosting circuit, and outputs a high voltage to the X-ray generation unit 310. The DAS 351 includes an amplification circuit and an A/D conversion circuit, and outputs, as digital data, a signal from the X-ray detection unit 320 to the signal processing unit 352.

The signal processing unit 352 includes a Central Processing Unit (CPU), a Read Only Memory (ROM), and a Random Access Memory (RAM), and can execute image processing and the like for the digital data. The display unit 353 includes a flat display apparatus or the like, and can display an X-ray image. The control unit 354 includes a CPU, a ROM, a RAM, and the like, and controls the operation of the overall X-ray CT apparatus 30.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-030345, filed February 27, 2025, which is hereby incorporated by reference herein in its entirety.

What is claimed is:

1. A photoelectric conversion apparatus that includes a semiconductor layer including a first surface and a second surface, wherein
the semiconductor layer includes a first semiconductor region of a first conductivity type extending from the first surface toward the second surface, a second semiconductor region of the first conductivity type arranged between the first semiconductor region and the second surface so as to contact the first semiconductor region, a third semiconductor region of a second conductivity type arranged between the second semiconductor region and the second surface, and a fourth semiconductor region of the second conductivity type arranged in contact with the third semiconductor region so as to surround the second semiconductor region and the third semiconductor region, and
a width of the second semiconductor region in a direction parallel to the first surface is larger than a width of the first semiconductor region in the direction, and smaller than a width of the third semiconductor region in the direction.

2. The apparatus according to claim 1, wherein
the width of the second semiconductor region in a direction parallel to the first surface is not less than two times and not more than four times of the width of the first semiconductor region in the direction.

3. The apparatus according to claim 1, wherein
the semiconductor layer further includes a fifth semiconductor region including a portion arranged between the second semiconductor region and the first surface so as to surround the first semiconductor region, and
an impurity concentration of the first conductivity type in the fifth semiconductor region is lower than an impurity concentration of the first conductivity type in each of the first semiconductor region and the second semiconductor region.

4. The apparatus according to claim 3, wherein
the fifth semiconductor region is one of a semiconductor region of the first conductivity type, an intrinsic semiconductor region, and a semiconductor region of the second conductivity type.

5. The apparatus according to claim 3, wherein
the first semiconductor region and the second semiconductor region include a region where an impurity concentration of the first conductivity type is not less than 1 × 10¹⁷ cm⁻³ and
the fifth semiconductor region includes a region where an impurity concentration of the first conductivity type is not more than 1 × 10¹⁶ cm⁻³.

6. The apparatus according to claim 1, wherein
the semiconductor layer further includes a fifth semiconductor region arranged between the first surface and the third semiconductor region so as to surround the first semiconductor region and a side surface of the second semiconductor region, and an impurity concentration of the first conductivity type in the fifth semiconductor region is lower than an impurity concentration of the first conductivity type in each of the first semiconductor region and the second semiconductor region.

7. The apparatus according to claim 6, wherein
the fifth semiconductor region includes a portion arranged between the second semiconductor region and the third semiconductor region.

8. The apparatus according to claim 1, wherein
the fourth semiconductor region is arranged so as not to surround the first semiconductor region.

9. The apparatus according to claim 1, wherein
a dimension of the second semiconductor region in a thickness direction of the semiconductor layer is not less than 0.8 times and less than two times of a dimension of the first semiconductor region in a thickness direction of the semiconductor layer.

10. The apparatus according to claim 1, wherein
the first semiconductor region and the second semiconductor region include a portion where a width in the direction decreases toward the first surface.

11. The apparatus according to claim 1, wherein
the second semiconductor region has a ring shape.

12. A photoelectric conversion apparatus that includes a semiconductor layer including a first surface and a second surface, wherein
the semiconductor layer includes a first semiconductor region of a first conductivity type extending from the first surface toward the second surface, a second semiconductor region of the first conductivity type arranged between the first semiconductor region and the second surface so as to contact the first semiconductor region, a third semiconductor region of a second conductivity type arranged between the second semiconductor region and the second surface, a fourth semiconductor region of the second conductivity type arranged in contact with the third semiconductor region so as to surround the first semiconductor region, the second semiconductor region, and the third semiconductor region, and a pixel isolation portion arranged so as to surround the fourth semiconductor region, and
a width of the second semiconductor region in a direction parallel to the first surface is smaller than a spacing between the second semiconductor region and the pixel isolation portion in the direction.

13. The apparatus according to claim 12, wherein
the width of the second semiconductor region in the direction is not less than two times and not more than four times of the width of the first semiconductor region in the direction.

14. The apparatus according to claim 12, wherein
the semiconductor layer further includes a fifth semiconductor region including a portion arranged between the second semiconductor region and the first surface so as to surround the first semiconductor region, and
an impurity concentration of the first conductivity type in the fifth semiconductor region is lower than an impurity concentration of the first conductivity type in each of the first semiconductor region and the second semiconductor region.

15. The apparatus according to claim 12, wherein
a plurality of pixels are provided,
each pixel includes an active region including the first semiconductor region, the second semiconductor region, and the third semiconductor region,
the active region includes a sixth semiconductor region arranged between the third semiconductor region and the second surface, and
the fourth semiconductor region includes a portion arranged between the pixel isolation portion and the sixth semiconductor region.

16. The apparatus according to claim 15, wherein
the semiconductor layer further includes a fifth semiconductor region arranged between the first surface and the third semiconductor region so as to surround the first semiconductor region and a side surface of the second semiconductor region, and an impurity concentration of the first conductivity type in the fifth semiconductor region is lower than an impurity concentration of the first conductivity type in each of the first semiconductor region and the second semiconductor region.

17. The apparatus according to claim 12, wherein
the fourth semiconductor region is arranged so as not to surround the first semiconductor region.

18. The apparatus according to claim 12, wherein
the first semiconductor region and the second semiconductor region include a portion where a width in the direction decreases toward the first surface.

19. The apparatus according to claim 12, wherein
the second semiconductor region has a ring shape.

20. A photoelectric conversion system comprising:
a photoelectric conversion apparatus defined in claim 1; and
a signal processing unit configured to process a signal output from the photoelectric conversion apparatus.
